(19) United States
(12) Patent Application Publication
(10) Pub. No.: US 2005/0189596 A1
(43) Pub. Date: Sep. 1, 2005

(54) Manufacturing method of the semiconductor device and the semiconductor device

(76) Inventor: Hirotsugu Takahashi, Sakata-shi (JP)

Correspondence Address: HARNESS, DICKEY & PIERCE, P.L.C., P.O. BOX 828, BLOOMFIELD HILLS, MI, 48303, US

(21) Appl. No.: 11/034,215

(22) Filed: Jan. 12, 2005

(30) Foreign Application Priority Data
Jan. 13, 2004 (JP) 2004-005700

(51) Int. Cl. H01L 21/336; H01L 29/76; H01L 31/062

(52) U.S. Cl. 257/369; 438/197; 438/199

(57) ABSTRACT

A method to impede the constitution of the area wherein the silicide film that is defying to form on a gate electrode. Form an element isolation film, and then a gate dielectric film in a P-channel and an N-channel transistor forming region respectively. Then form a semiconductor film that constructs part of a gate electrode over the P-Type and the N-Type element regions through the element isolation film. Implant a dopant into the region, including the part over the P-channel transistor forming region and form a P-Type gate region, and then implant a dopant into the region, including the part over the N-channel transistor forming region and form a N-Type gate region. At this time, form the region so part of the P-Type gate region and the N-Type gate region overlap. Then, form the silicide film that constructs the part of the gate electrode over the semiconductor film.

### RELATED APPLICATIONS

This application claims priority to Japanese Patent Application No. 2004-005700 filed Jan. 13, 2004 which is hereby expressly incorporated by reference herein in its entirety.

### BACKGROUND

1. Technical Field

The present invention relates to a semiconductor device manufacturing method and the semiconductor device. Particularly, the present invention relates to the semiconductor device manufacturing method and the semiconductor device which sets back the constitution of the area wherein the suicide film becomes highly-resistant on a surface of a gate electrode.

2. Related Art

FIG. 12(a) is a sectional drawing that shows the conventional manufacturing method of the semiconductor device, whereby a gate electrode is formed with a polysilicon pattern and a cobalt silicide film. First, as shown in FIG. 12(a), an element isolation film 102 is formed over a silicon substrate 101 using the Local Oxidation of Silicon (LOCOS) model. The element isolation film 102 isolates a P-channel transistor forming region 102a where the P-channel transistor is supposed to be formed, and an N-channel transistor forming region 102b where the N-channel transistor is supposed to be formed, from the substrate. Then, in the P-channel transistor forming region 102a and the N-channel transistor forming region 102b respectively, an N-Type well 101a and a P-Type well 101b are formed on the silicon substrate 101, and then the gate dielectric films 103a and 103b are formed on each surface of the N-Type well 101a and the P-Type well 101b with thermal oxide. After that, a polysilicon pattern 104 that constructs the gate electrode is formed by heaping a polysilicon film over the entire surface, including over the element isolation film 102 as well as the gate dielectric films 103a and 103b, and by patterning this polysilicon film. The polysilicon pattern 104 extends from over the gate dielectric film 103a crossing the element isolation film 102 over to the gate dielectric film 103b.

Further, the P-channel transistor forming region 102a, as well as the half of the polysilicon pattern 104 that is on the side of the P-channel transistor forming region 102a, are covered with a resistive pattern 110. Then, by implanting the ion of N-Type dopant, while using the resistive pattern 110 as a mask, N-Type dopant layers (not shown) are formed in the N-channel transistor forming region 102b, which become source and drain regions for N-channel transistor. Here, the ion of N-Type dopant is also implanted into the other half of the polysilicon pattern 104 that is on the side of the N-channel transistor forming region 102b, and an N-Type gate region 104b is formed.

Moreover, as shown in FIG. 12(b), after removing the resistive pattern 110, the N-channel transistor forming region 102b, as well as the half of the polysilicon pattern 104 that is on the side of the N-channel transistor forming region 102b, are covered with a resistive pattern 112. Then, by implanting the ion of P-Type dopant, while using the resistive pattern 112 as a mask, P-Type dopant layers (not shown) are formed in the P-channel transistor forming region 102a, which become source and drain regions for P-channel transistor. At the same time, the ion of P-Type dopant is also implanted into the other half of the polysilicon pattern 104 that is on the side of the P-channel transistor forming region 102a, and a P-Type gate region 104a is formed.

Then, as shown in FIG. 12(c), a cobalt film is formed over the entire surface including the polysilicon pattern 104, after removing the resistive pattern 112. Then, a cobalt suicide film 109 that constructs the gate electrode on the polysilicon pattern 104 is formed by annealing the polysilicon pattern 104 and the cobalt film. The cobalt film that is not formed into silicide is then removed.

Such technologies are described in Japanese Unexamined Patent Publication No. 2003-179158 (Paragraph 4 through 6, FIG. 3).

In order to form a cobalt silicide film by annealing the polysilicon pattern and the cobalt film, it is preferable that enough dopants are contained in the polysilicon pattern. However, if the location of a resistive pattern is misaligned upon conducting the ion implantation, the region wherein enough dopants are not introduced to the polysilicon pattern may emerge, for example, such as a numeral 104c shown in FIG. 12(b). This region has a low density of dopants, thus the cobalt film is formed into silicide insufficiently, and hence the resistance of the cobalt silicide film may disperse high due to the “small diameter wire effect”.

In view of the above-mentioned issues, the present invention is intended to provide the semiconductor device manufacturing method and the semiconductor device which impede the constitution of the area wherein the silicide film becomes highly-resistant on a surface of a gate electrode.

### SUMMARY

In order to solver the above-mentioned problems, the semiconductor device manufacturing method in the present invention is provided as follows. A semiconductor device manufacturing method with each gate electrode of an adjacent first conduction type transistor and a second conduction type transistor being connected, the semiconductor device manufacturing method comprising:
a process for forming an element isolation film, for isolating a first conduction type transistor forming region and a second conduction type transistor forming region on the semiconductor substrate;
a process for forming gate dielectric film on each of the first conduction type transistor forming region and the second conduction type transistor forming region;
a process for forming a gate electrode on the two gate dielectric film and the element isolation film;
a process for forming a first conduction type gate region as well as implanting a first conduction type dopant into the a gate electrode located on the first conduction type transistor forming region and on the part of the element isolation film;
a process for forming a second conduction type gate region as well as implanting a second conduction type dopant into the gate electrode located on the second conduction type transistor forming region and on the other part of the element isolation film; and
a process for forming a suicide film over the surface of the gate electrode;
wherein in the process for forming the second conduction type gate region, the second conduction type dopant is implanted in a way that overlaps with the part of the first conduction type gate electrode on the element isolation film.

With this semiconductor device manufacturing method, the first conduction type gate region and the second conduction type gate region are formed overlapping each other at their edges. Therefore, even if the positions of the first conduction type gate region and the second conduction type gate region are misaligned, it is less likely that the region wherein the ion of dopant is not sufficiently implanted is formed in the gate electrode. Consequently, this makes the formation of the cobalt silicide film that is sufficiently formed into silicide in any part on the gate electrode easier. Hence the resistance of the silicide film is less likely to disperse high.

The process for forming the first conduction type gate region as well as the process for forming the second conduction type gate region may respectively be provided with an implanting process of dopant, by forming a resist film on the region where the dopant is not implanted in the gate electrode, and implanting an ion using the resist film as a mask.

In the process for forming the first conduction type gate region, dopant layers which become source and drain regions for the first conduction type transistor may be formed, by forming the resist film also on the second conduction type transistor forming region, as well as by conducting the implant of ion into the semiconductor substrate that is located in the first conduction type transistor forming region, while using the resist film, the element isolation film and the gate electrode as masks. In the process for forming the second conduction type gate region, dopant layers which become source and drain regions for the second conduction type transistor may be formed, by forming the resist film also on the first conduction type transistor forming region, as well as by conducting the implant of ion into the semiconductor substrate that is located in the second conduction type transistor forming region, while using the resist film, the element isolation film and the gate electrode as masks.

Another semiconductor device manufacturing method in the present invention is provided as follows. A semiconductor device manufacturing method with each gate electrode of an adjacent first conduction type transistor and a second conduction type transistor being connected, the semiconductor device manufacturing method comprising:
a process for forming an element isolation film, for isolating a first conduction type transistor forming region and a second conduction type transistor forming region on the semiconductor substrate;
a process for forming gate dielectric film on each of the first conduction type transistor forming region and the second conduction forming region;
a process for forming a semiconductor film on the gate dielectric film and on the element isolation film;
a process for implanting a first conduction type dopant into the semiconductor film located on the part of the element isolation film and on the first conduction type transistor forming region;
a process for forming a gate electrode that is composed with the semiconductor film, on the element isolation film and on the gate dielectric film, by patterning the semiconductor film; a process for implanting a second conduction type dopant into the gate electrode located on the part of the element isolation film and on the second conduction type transistor forming region;
a process for forming a silicide film over the surface of the gate electrode;
wherein in the process for implanting the second conduction type dopant into the gate electrode, the second conduction type dopant is implanted in a way that the gate electrode into which the first conduction type dopant is implanted overlaps on the element isolation film.

With this semiconductor device manufacturing method, it is also less likely that the region wherein the ion of dopant is not sufficiently implanted is formed in the gate electrode, even if the positions of the first conduction type gate region and the second conduction type gate region are misaligned. Consequently, this makes the formation of the cobalt silicide film that is sufficiently formed into silicide in any part on the gate electrode easier. Hence the resistance of the silicide film is less likely to disperse high.

In this semiconductor device manufacturing method, the followings may be further provided. A process for forming dopant layers which become source and drain regions for the first conduction type transistor, by implanting the first conduction type dopant into the semiconductor substrate that is located in the first conduction type transistor forming region, after the process for forming the gate electrode by patterning the semiconductor film, and in the process for implanting the second conduction type dopant into the gate electrode, the dopant layers which become source and drain regions for the second conduction type transistor are further formed, by implanting the second conduction type dopant into the semiconductor substrate that is located in the second conduction type transistor forming region.

In the process for implanting a first conduction type dopant into the semiconductor film, the semiconductor film may be formed at a distance of at least 0.5 μm from a channel region of the second conduction type transistor, into which the first conduction type dopant is implanted in that way.

The semiconductor device in the present invention is provided as follows. A semiconductor device with each gate electrode of an adjacent first conduction type transistor and a second conduction type transistor being connected, the semiconductor device comprising:
an element isolation film formed on a semiconductor substrate, and isolating a first conduction type transistor forming region and a second conduction type transistor forming region;
gate dielectric film, located on the semiconductor substrate, and formed in the first conduction type transistor forming region and the second conduction type transistor forming region;
a first conduction type gate region, formed on the part of the element isolation film and on the gate electrode located on the first conduction type channel transistor forming region, and infused with a first conduction type dopant;
a second conduction type gate region, formed on the part of the element isolation film and on the gate electrode located on the second conduction type channel transistor forming region, and infused with a second conduction type dopant; and
a silicide film formed on the surface of the gate electrode;
wherein the second conduction type gate region is formed to overlap with the part of the first conduction type gate region over the element isolation film.

In this semiconductor device, the silicide film may be a cobalt silicide film. It is desirable that the length of the overlapping part of the first conduction type gate region and the second conduction type gate region is at least 0.1 μm. Desirably, the length of the overlapping part of the first conduction type gate region and the second conduction type gate region is at least 0.1 μm. It is desired that the overlapping part of the first conduction type gate region and the second conduction type gate region is set apart at least 0.24 μm from the either of the channel regions that the transistors have.

The present invention is especially effective when the width of the gate electrode is 0.25 μm or less.

### BRIEF DESCRIPTION OF THE DRAWINGS

FIG. 1 is a top view drawing that shows the main parts of the semiconductor device in the first embodiment.

FIG. 2 is a drawing that shows the manufacturing method of the semiconductor device shown in FIG. 1. FIG. 2(a) is a sectional drawing that corresponds to the section A-A of the FIG. 1. FIG. 2(b) is a sectional drawing that corresponds to the section B-B of the FIG. 1. FIG. 2(c) is a sectional drawing that corresponds to the section C-C of the FIG. 1.

FIG. 3 is a drawing that shows the next process after that of FIG. 1. FIG. 3(a) is a sectional drawing that corresponds to the section A-A of the FIG. 1. FIG. 3(b) is a sectional drawing that corresponds to the section B-B of the FIG. 1. FIG. 3(c) is a sectional drawing that corresponds to the section C-C of the FIG. 1.

FIG. 4 is a drawing that shows the next process after that of FIG. 3. FIG. 4(a) is a sectional drawing that corresponds to the section A-A of the FIG. 1. FIG. 4(b) is a sectional drawing that corresponds to the section B-B of the FIG. 1. FIG. 4(c) is a sectional drawing that corresponds to the section C-C of the FIG. 1.

FIG. 5 is a drawing that shows the next process after that of FIG. 4. FIG. 5(a) is a sectional drawing that corresponds to the section A-A of the FIG. 1. FIG. 5(b) is a sectional drawing that corresponds to the section B-B of the FIG. 1. FIG. 5(c) is a sectional drawing that corresponds to the section C-C of the FIG. 1.

FIG. 6 is a drawing that shows the next process after that of FIG. 5. FIG. 6(a) is a sectional drawing that corresponds to the section A-A of the FIG. 1. FIG. 6(b) is a sectional drawing that corresponds to the section B-B of the FIG. 1. FIG. 6(c) is a sectional drawing that corresponds to the section C-C of the FIG. 1.

FIG. 7 is a drawing that shows the manufacturing method of the semiconductor device in the second embodiment. FIG. 7(a) is a sectional drawing that corresponds to the section A-A of the FIG. 1. FIG. 7(b) is a sectional drawing that corresponds to the section B-B of the FIG. 1. FIG. 7(c) is a sectional drawing that corresponds to the section C-C of the FIG. 1.

FIG. 8 is a drawing that shows the next process after that of FIG. 7. FIG. 8(a) is a sectional drawing that corresponds to the section A-A of the FIG. 1. FIG. 8(b) is a sectional drawing that corresponds to the section B-B of the FIG. 1. FIG. 8(c) is a sectional drawing that corresponds to the section C-C of the FIG. 1.

FIG. 9 is a drawing that shows the next process after that of FIG. 8. FIG. 9(a) is a sectional drawing that corresponds to the section A-A of the FIG. 1. FIG. 9(b) is a sectional drawing that corresponds to the section B-B of the FIG. 1. FIG. 9(c) is a sectional drawing that corresponds to the section C-C of the FIG. 1.

FIG. 10 is a drawing that shows the next process after that of FIG. 9. FIG. 10(a) is a sectional drawing that corresponds to the section A-A of the FIG. 1. FIG. 10(b) is a sectional drawing that corresponds to the section B-B of the FIG. 1. FIG. 10(c) is a sectional drawing that corresponds to the section C-C of the FIG. 1.

FIG. 11 is a drawing that shows the next process after that of FIG. 10. FIG. 11(a) is a sectional drawing that corresponds to the section A-A of the FIG. 1. FIG. 11(b) is a sectional drawing that corresponds to the section B-B of the FIG. 1. FIG. 11(c) is a sectional drawing that corresponds to the section C-C of the FIG. 1.

FIG. 12(a) is a sectional drawing that shows the conventional manufacturing method of the semiconductor device. FIG. 12(b) is a sectional drawing that shows the next process after the process shown in FIG. 12(a). FIG. 12(c) is a sectional drawing that shows the next process after the process shown in FIG. 12(b).

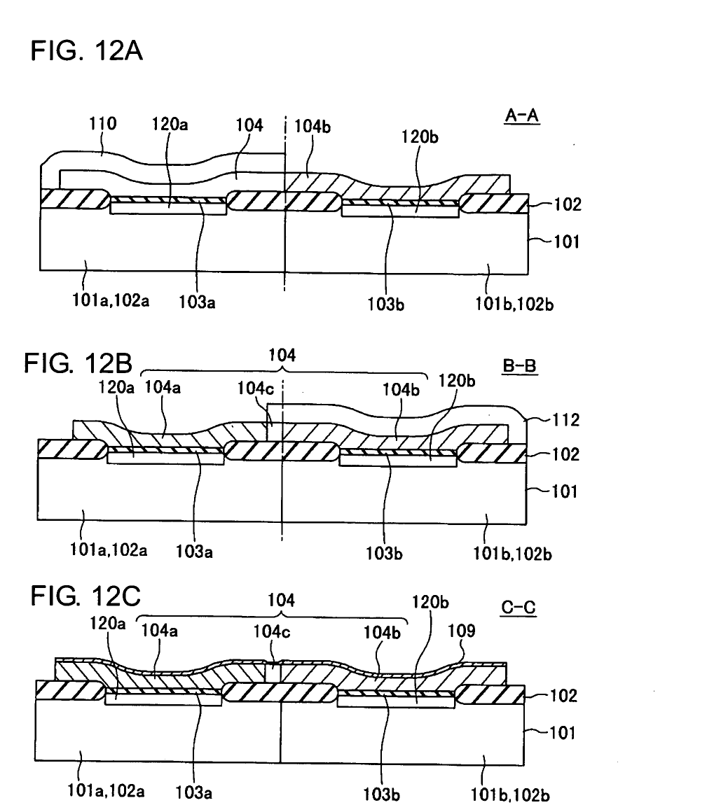

### DETAILED DESCRIPTION

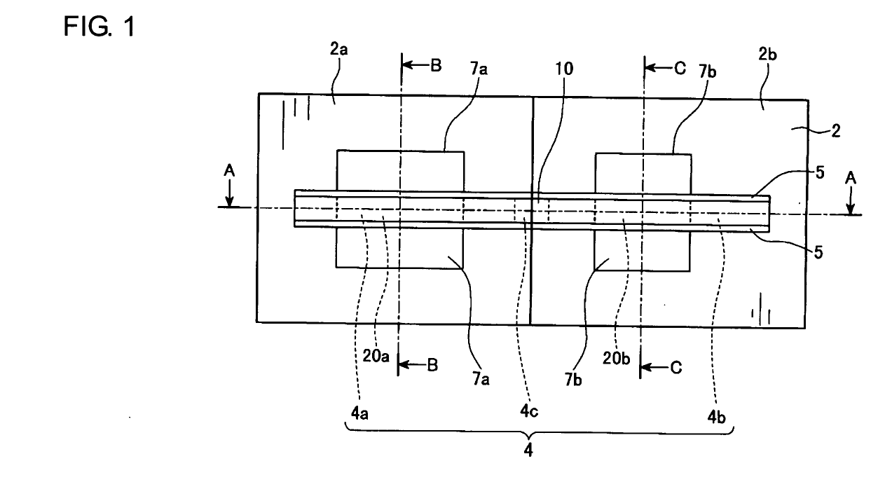

The embodiment of the present invention will now be described with reference to the accompanying drawings. FIG. 1 is a top view drawing that shows the main parts of the semiconductor device in the first embodiment. In this semiconductor device, a P-channel transistor forming region 2a is adjacent to an N-channel transistor forming region 2b. In the P-channel transistor forming region 2a, P-Type dopant layers 7a that becomes the source and the drain regions of a P-channel MOS transistor is formed, and in the N-channel transistor forming region 2b, N-Type dopant layers 7b that become the source and the drain regions of a N-channel MOS transistor are formed. Both the P-channel MOS transistor and the N-channel transistor are isolated by an element isolation film 2.

A P-Type gate electrode of the P-channel MOS transistor and an N-Type gate electrode of the N-channel MOS transistor are formed as one part as a gate electrode 10. Both edges of the gate electrode 10 are located on the element isolation film 2, having a patterned formation wherein the parts between those edges respectively go through the element isolation film 2. The width of the gate electrode 10 is, for example, 0.25 μm or less, and it is structured with a cobalt silicide film formed on a polysilicon pattern 4. The polysilicon pattern 4 is structured with a P-Type gate region 4a that corresponds to the P-Type gate electrode, and with an N-Type gate region 4b that corresponds to the N-Type gate electrode, overlapping with each other in an overlapping region 4c. In addition, on both sides of the gate electrode 10, sidewalls 5 made of silicon nitride film are formed.

Moreover, in the P-channel transistor forming region 2a, a P-Type channel region 20a located under the P-Type gate region 4a is formed, and in the N-channel transistor forming region 2b, an N-Type channel region 20b located under the N-Type gate region 4b is formed.

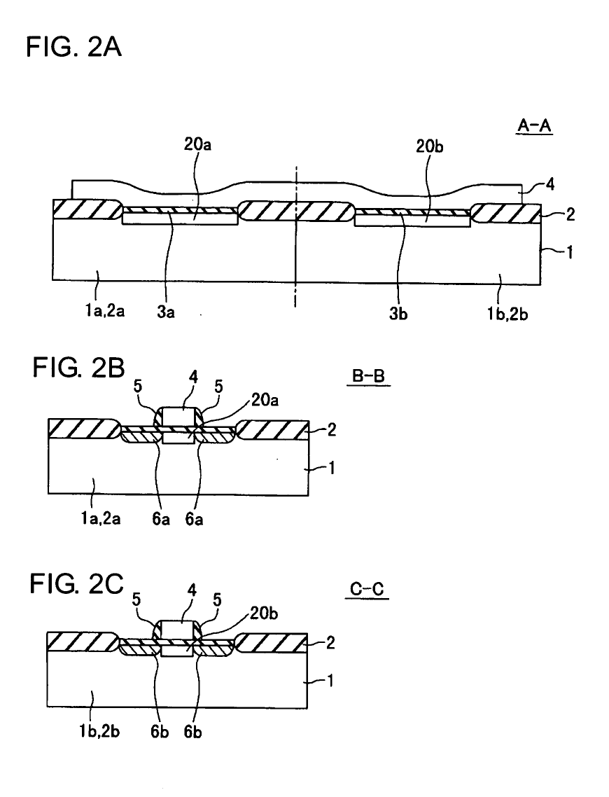

Hereafter, a method of manufacturing the semiconductor device shown in FIG. 1 is described using FIG. 2 through FIG. 6. In each of the figures, (a) represents a sectional drawing that corresponds to the section A-A of the FIG. 1, (b) represents a sectional drawing that corresponds to the section B-B of the FIG. 1, and (c) represents a sectional drawing that corresponds to the section C-C of the FIG. 1.

First, as shown in the drawings in the FIG. 2, the element isolation film 2 is formed on a silicon substrate 1, one example of a semiconductor substrate, using the LOCOS model. At this time, apertures located on the P-channel transistor forming region 2a and on the N-channel transistor forming region 2b are formed on the element isolation film 2. Then, the N-channel transistor forming region 2b is covered with the resistive pattern (not shown), and then, an ion of N-Type dopant is implanted into the silicon substrate 1 using the resistive pattern and the element isolation film 2 as masks. After that, the resistive pattern is removed, and the P-channel transistor forming region 2a is covered with another resistive pattern (not shown). Then, after implanting an ion of P-Type dopant into the silicon substrate 1 using the resistive pattern and the element isolation film 2 as masks, an N-Type well 1a located in the P-channel transistor forming region 2a, and a P-Type well 1b located in the N-channel transistor forming region 2b are formed in the silicon substrate 1, by thermal processing of the silicon substrate 1.

After that, a gate dielectric film 3a located on the N-Type well 1a and a gate dielectric film 3b located on the P-Type well 1b are respectively formed on the P-channel transistor forming region 2a and the N-channel transistor forming region 2b, by using the thermal oxide model. Then, the polysilicon film is formed over the entire surface including the element isolation film 2 and the gate dielectric film 3a and 3b, using, for example, the Chemical Vapor Deposition (CVD) model. Then a photoresist film (not shown) is coated on this polysilicon film, and by conducting light exposure and photo finishing this photoresist film, the resistive pattern is formed. The polysilicon pattern 4 that constructs the gate electrode 10 is then formed by etching the polysilicon film using this resistive pattern as a mask. The patterned formation of the polysilicon pattern 4 is identical to that of the gate electrode 10 described in the FIG. 1.

Here, the part of the N-Type well 1a located under the polysilicon pattern 4 becomes the P-Type channel region 20a, and the part of the P-Type well 1b located under the polysilicon pattern 4 becomes the N-Type channel region 20b.

Then, after covering the N-channel transistor forming region 2b with the resistive pattern (not shown), a P-Type low-density dopant layer (Lightly Doped Drain) 6a is formed in the P-channel transistor forming region 2a, by implanting the ion of P-Type low-density dopant, while using this resistive pattern, the element isolation film 2 and the polysilicon pattern 4 as masks. Then, after removing the resistive pattern, the P-channel transistor forming region 2a is covered with another resistive pattern (not shown). An N-Type low-density dopant layer (LDD) 6b is formed in the N-channel transistor forming region 2b, by implanting the ion of N-Type low-density dopant, while using this resistive pattern, the element isolation film 2 and the polysilicon pattern 4 as masks.

Then, after removing the resistive pattern, the silicon nitride film is formed over the entire surface including the upper and both of the side surfaces of the polysilicon pattern 4, using, for example, the CVD model. Further, by etching back the silicon nitride, (the side walls 5 are formed on both of the side surfaces of the polysilicon pattern 4.

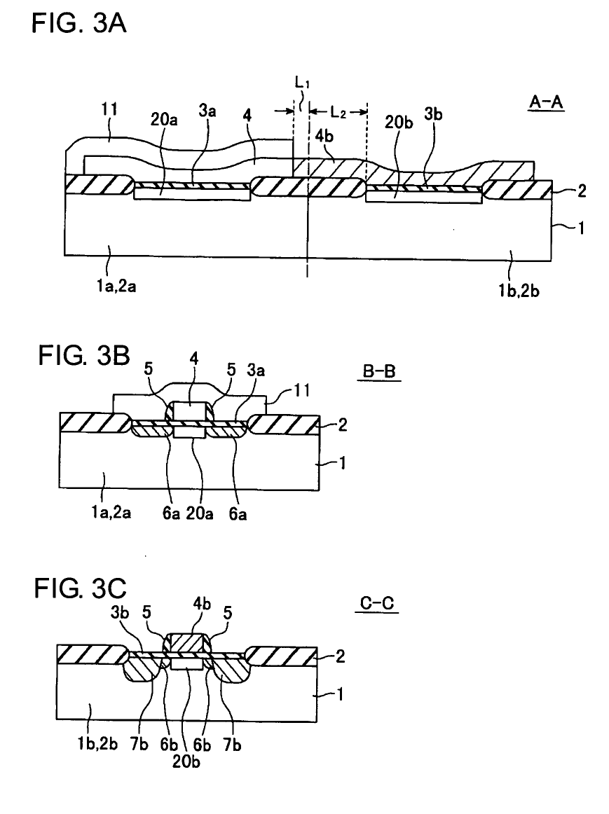

Then, as shown in the drawings of FIG. 3, the above part of the P-channel transistor forming region 2a, as well as the part on the side of the P-channel transistor forming region 2a in the polysilicon pattern 4, are covered with a resistive pattern 11. At this time, the edge of the resistive pattern 11 is positioned towards the side of the P-channel transistor forming region 2a by the distance of L1, from the perimeter between the P-channel transistor forming region 2a and the N-channel transistor forming region 2b. The distance L1 is preferably at least 0.05 μm. Here, a distance L2 between the edge of the resistive pattern 11 and the P-Type channel region 20a is at least 0.24 μm.

Then, the N-Type dopant layers 7b that become the source and the drain regions of the N-channel transistor forming region 2b are formed, by implanting the ion of the N-Type dopant in a self-aligned way, while using the resistive pattern 11, the polysilicon pattern 4, the side walls 5, and the element isolation film 2 as masks. At this time, an ion of the N-Type dopant is implanted also into the part in the polysilicon pattern 4 that is not covered by the resistive pattern 11, hence the N-Type gate region 4b is formed in the polysilicon pattern 4. The N-Type gate region 4b is located on the N-channel transistor forming region 2b, as well as on some part of the element isolation film 2, while edge part of the N-Type gate region 4b side is positioned toward the side of the P-channel transistor forming region 2a at a distance of L1, from the perimeter between the P-channel transistor forming region 2a and the N-channel transistor forming region 2b.

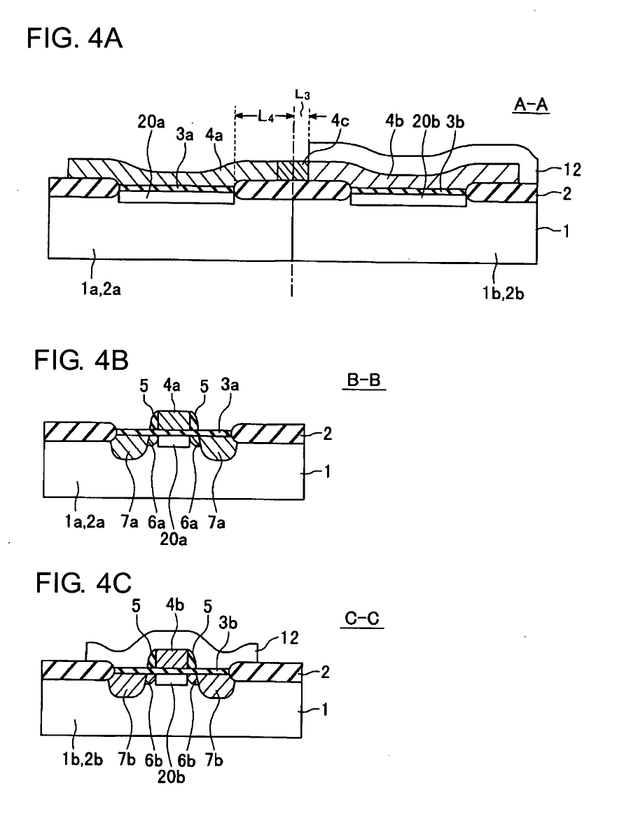

Then, as shown in the drawings of FIG. 4, after removing the resistive pattern 11, on the N-channel transistor forming region 2b and the N-Type gate region 4b are covered with a resistive pattern 12. At this time, the edge of the resistive pattern 12 is positioned towards the side of the N-channel transistor forming region 2b at a distance of L3, from the perimeter between the P-channel transistor forming region 2a and the N-channel transistor forming region 2b. The distance L3 is preferably at least 0.05 μm. Thus the edge part on the P-channel transistor forming region 2a side is uncovered by the resistive pattern 12 by at least 0.1 μm. Here, a distance L4 between the edge of the resistive pattern 12 and the N-Type channel region 20b is at least 0.24 μm.

Then, the P-Type dopant layers 7a that become the source and the drain regions of the P-channel transistor forming region 2a are formed, by implanting the ion of the P-Type dopant in self-alignment, while using the resistive pattern 12, the polysilicon pattern 4, the side walls 5, and the element isolation film 2 as masks. At this time, an ion of the P-Type dopant is implanted also into some part of the polysilicon pattern 4 that is not covered by the resistive pattern 12, hence the P-Type gate region 4a is formed in the polysilicon pattern 4. The P-Type gate region 4a is located on the P-channel transistor forming region 2a, as well as on some part of the element isolation film 2. Here, the edge part of the N-Type gate region 4b is uncovered by the resistive pattern 12, and into this uncovered part, both the N-Type and P-Type dopants are implanted, and it becomes the overlapping region 4c. Since the overlapping region 4c is formed, even if the misalignment occurs for resistive pattern 11 and 12, it is less likely that the region wherein the ion of dopant is not implanted is formed in the polysilicon pattern 4.

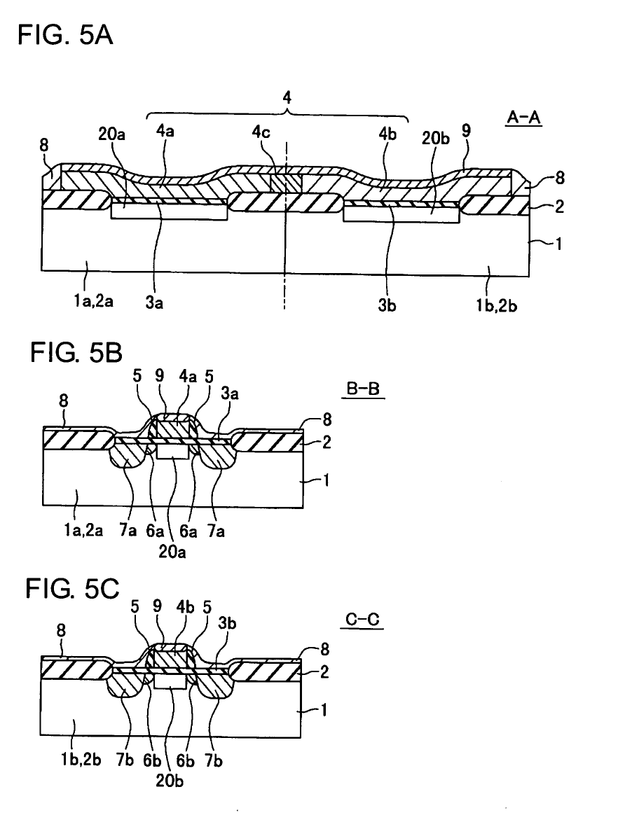

Then, as shown in the drawings of FIG. 5, a cobalt film 8 is formed over the entire surface including the upper surface of the polysilicon pattern 4, by, for example, sputtering. Further, a cobalt silicide film 9 is formed on the polysilicon pattern 4, by annealing the polysilicon pattern 4 and the cobalt film 8. At this time, it is less likely that the region, wherein the ion of dopant is not implanted, is formed in the polysilicon pattern 4, thus this makes the cobalt silicide film 9 which is sufficient silicide formation in the entire part of the polysilicon pattern 4 easier.

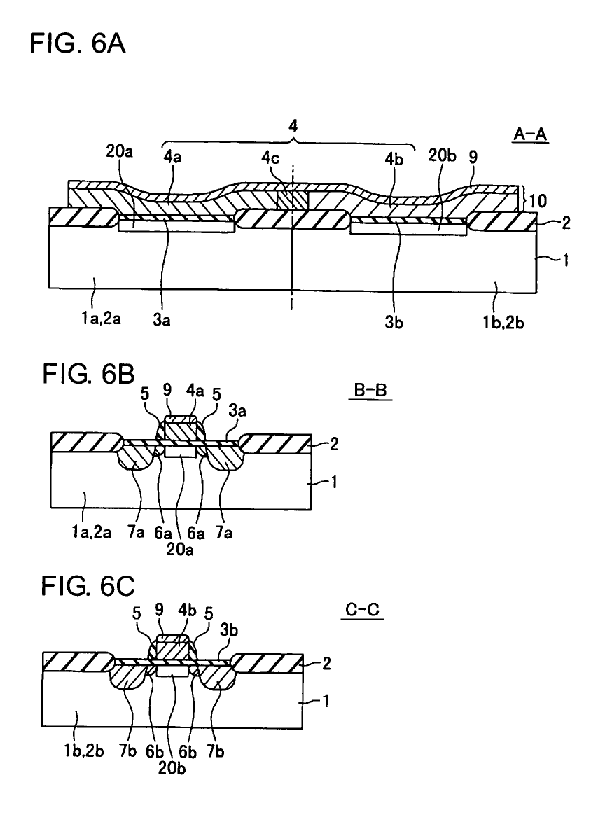

The cobalt film 8 that is not formed into silicide is then removed by etching, as shown in drawings of FIG. 6.

The semiconductor device formed in such processes has the following sectional structure, as shown in FIG. 6. More specifically, the P-channel transistor forming region 2a, as well as the N-channel transistor forming region 2b are isolated from the silicon substrate 1, by the element isolation film 2. In the P-channel transistor forming region 2a, the P-channel MOS transistor is formed, and in the N-channel transistor forming region 2b, the N-channel MOS transistor is formed. These two gate electrodes are interconnected, and form the gate electrode 10. The gate electrode 10 is formed with the polysilicon pattern 4 and the cobalt silicide film 9, and both edges thereof are located on the element isolation film 2, having a patterned formation wherein the parts between those edges cross on the gate dielectric film 3a and 3b, going through the element isolation film 2. On both sides of the gate electrode 10, sidewalls 5 are formed. Moreover, in the P-channel transistor forming region 2a, the N-Type well 1a is formed, and in the N-channel transistor forming region 2b, the P-Type well 1b is formed. In the N-Type well 1a, the P-Type dopant layers 7a that are the source and the drain regions of the P-channel MOS transistor, P-Type low-density dopant layers 6a, and the P-Type gate region 4a of the gate electrode 10 are formed. In the P-Type well 1b, the N-Type dopant layers 7b that are the source and drain regions of the N-channel MOS transistor, N-Type low-density dopant layers 6b, and the N-Type gate region 4b of the gate electrode 10 are formed. The P-Type gate region 4a and N-Type gate region 4b are overlapping with each other and forming an overlapping region 4c on the element isolation film 2.

As described above, with this present embodiment, by inter overlapping the edge of the P-Type gate region 4a and the N-Type gate region 4b on the element isolation film 2 in the polysilicon pattern 4, the overlapping region 4c is formed on the element isolation film 2. Thus it is less likely that the region wherein the ion of dopant is not implanted is formed in the polysilicon pattern 4, hence the region with low dopant density is not likely to be formed in it. For this reason, when forming the cobalt film on the polysilicon pattern 4 and annealing it, the formation of the cobalt silicide film 9 that is sufficiently formed into silicide in the entire part of the polysilicon pattern 4 becomes easier. Hence the high fluctuation of the resistance of the cobalt silicide film 9 can be suppressed.

Furthermore, since the edge of the resistive pattern 11 is set apart from the P-Type channel region 20a at a distance of 0.24 μm, and the edge of the resistive pattern 12 is set apart from the N-Type channel region 20b at a distance of 0.24 μm, the overlapping region 4c is formed at least 0.24 μm away from the P-Type channel region 20a and the N-Type channel region 20b respectively. Consequently, the dopants with a different electrode are not likely to diffuse from the overlapping region 4c into the part located on the P-Type channel region 20a in the P-Type gate region 4a, and into the part located on the N-Type channel region 20b in the N-Type gate region 4b, respectively. Therefore, the gate depletion caused by the inter diffusion of dopants is less likely to occur.

Moreover, it is also possible to implant either the P-Type dopant or the N-Type dopant into the entire polysilicon pattern 4, and then implant the other dopant into the other half of the polysilicon pattern 4. In comparison, the present embodiment limits the overlapping region 4c to the perimeter between the P-Type gate region 4a and the N-Type gate region 4b, thus the gate depletion in a polysilicon pattern, caused by the inter diffusion of dopants, is less likely to occur.

Depending on the configuration of the P-Type dopant layer 7a in the plane direction, the distance from the overlapping region 4c to the P-Type dopant layer 7a may be shorter than the distance from the overlapping region 4c to the channel region of the P-channel MOS transistor. In such a case, it is desirable to form the overlapping region 4c to have a distance of at least 0.15 μm to the P-Type dopant layers 7a, and to have a distance of at least 0.24 μm to the channel region. The same applies for the case where the distance of the overlapping region 4c to the N-Type dopant layers 7b is shorter than the distance of the overlapping region 4c to the channel region of the N-channel MOS transistor.

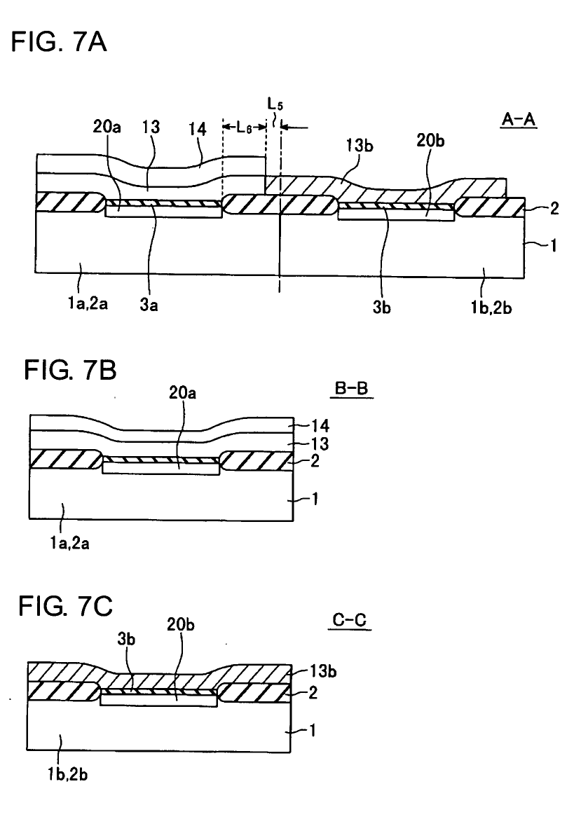

Hereafter, the semiconductor device manufacturing method in the second present embodiment is described using figures FIG. 7 through FIG. 11. The present embodiment manufactures the same semiconductor device, having almost the same structure in the first embodiment as a different method. The same reference numerals are used for the same structure as the first embodiment, and the description is omitted. In each of the figures FIG. 7 through FIG. 11, (a) represents a sectional drawing that corresponds to the section A-A of the FIG. 1, (b) represents a sectional drawing that corresponds to the section B-B of the FIG. 1, and (c) represents a sectional drawing that corresponds to the section C-C of the FIG. 1.

First, as shown in drawings of FIG. 7, the N-Type well 1a, the element isolation film 2, and the gate dielectric film 3a and 3b are formed on the silicon substrate 1 in the same method as of the first embodiment. Then, a polysilicon film 13 is formed on the entire surface including the element isolation film 2 and the gate dielectric film 3a and 3b, using, for example, the CVD model. After that, the part on the side of the P-channel transistor forming region 2a in the polysilicon film 13 is covered with a resistive pattern 14. At this time, the edge of the resistive pattern 14 is positioned towards the side of the P-channel transistor forming region 2a, at a distance of L5 from the perimeter between the P-channel transistor forming region 2a and the N-channel transistor forming region 2b. The distance L5 is preferably at least 0.1 μm. Here, a distance L6 between the edge of the resistive pattern 14 and the P-Type channel region 20a is at least 0.51 μm.

Then, after conducting the ion implantation of the N-Type dopant into the poly silicon film 13 using the resistive pattern 14 as a mask, an N-Type region 13b is formed on the polysilicon film 13 by annealing the polysilicon film 13. The edge part of the N-Type region 13b is deviated toward the P-channel transistor forming region 2a at a distance of L5 from the perimeter between the P-channel transistor forming region 2a and the N-channel transistor forming region 2b. At this time, the density of the ion implanted into the N-Type region 13b is higher than that of the N-Type dopant layer 7b described later. Moreover, the edge of the N-Type region 13b is formed to set apart from the P-Type channel region 20a at a the distance of 0.5 μm.

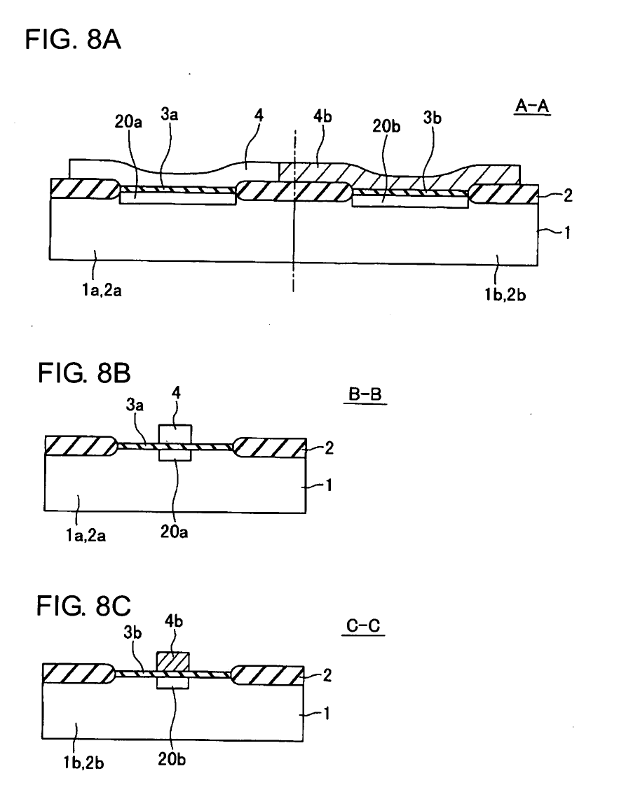

Then, as shown in the drawings of FIG. 8, the resistive pattern 14 is removed. Afterwards, a photoresist film (not shown) is coated, and by conducting light-exposure and photo-finishing this photoresist film, the resistive pattern is formed. The polysilicon pattern 4 that constructs the gate electrode 10 is then formed by etching the polysilicon film 13 using this resistive pattern as a mask. At this time, the N-Type region 13b of the polysilicon film 13 becomes the N-Type gate 4b of the polysilicon pattern 4. The edge of the N-Type gate 4n is deviated toward the P-channel transistor forming region 2a at a distance of L5 from the perimeter between the P-channel transistor forming region 2a and the N-channel transistor forming region 2b.

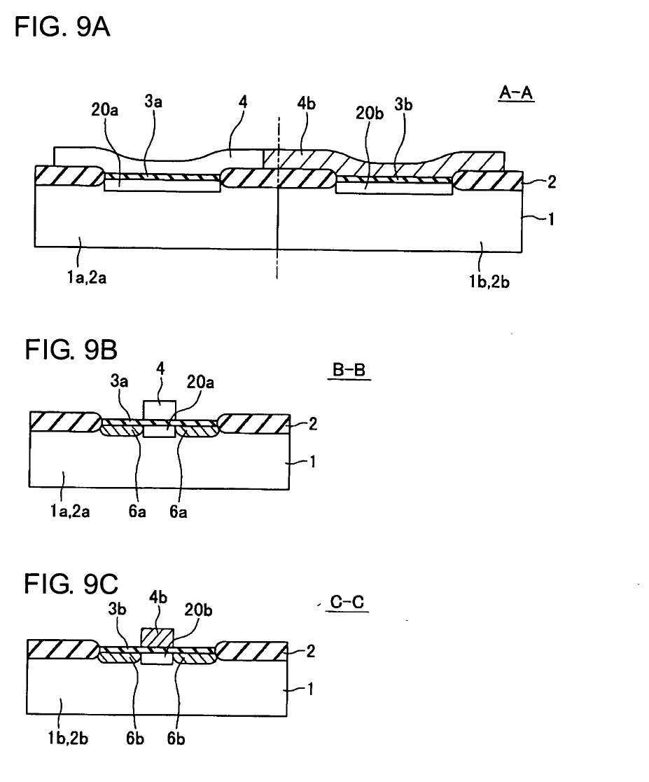

Then, as shown in the drawings of FIG. 9, with the same method as of the first embodiment, the P-Type low-density dopant layer (LDD) 6a is formed in the P-channel transistor forming region 2a, and the N-Type low-density dopant layer (LDD) 6b is formed in the N-channel transistor forming region 2b.

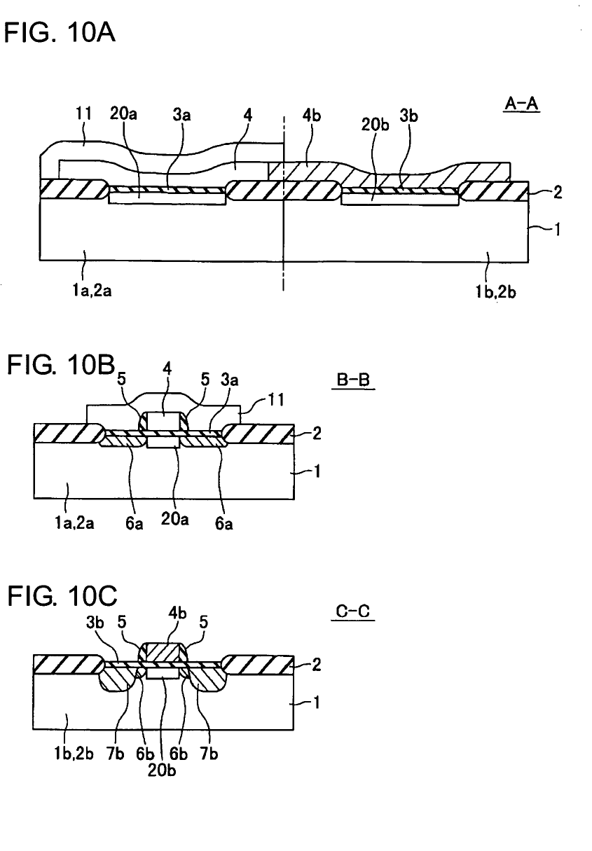

Then, as shown in the drawings of FIG. 10, with the same method as of the first embodiment, the side wall 5 is formed.

Thereafter, the parts including the upper surface of the N-channel transistor forming region 2b and on the side of the N-channel transistor forming region 2b in the polysilicon pattern 4 are covered with a resistive pattern 11. Here, the edge of the resistive pattern 11 is located on the perimeter of the P-channel transistor forming region 2a and the N-channel transistor forming region 2b. Then, by conducting the ion implantation using the resistive pattern 11, the polysilicon pattern 4, the side walls 5, and the element isolation film 2 as masks, the N-Type dopant layers 7b that become the source and the drain regions of the N-channel transistor forming region 2b are formed.

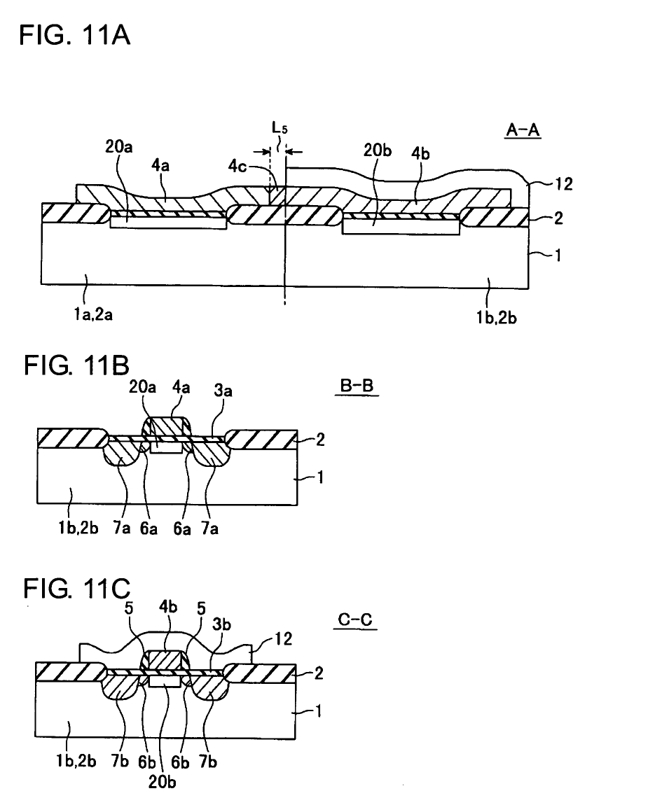

Then, as shown in the drawings of FIG. 11, after removing the resistive pattern 11, the N-channel transistor forming region 2b and the N-Type gate region 4b are covered with a resistive pattern 12. At this time, the edge of the resistive pattern 12 is positioned to the perimeter of the P-channel transistor forming region 2a and the N-channel transistor forming region 2b. Here, the edge of the N-Type gate region 4b is deviated towards the P-channel transistor forming region 2a at a distance of L5, from the perimeter of the P-channel transistor forming region 2a and the N-channel transistor forming area 2b, thus it is uncovered by the resistive pattern 12 and exposed at a distance of L5.

Thereafter, by conducting the ion implantation using the resistive pattern 12, the polysilicon pattern 4, the side walls 5, and the element isolation film 2 as masks, the P-Type dopant layers 7a that become the source and the drain regions of the P-channel transistor forming region 2a are formed. At this time, the ion is implanted also into some part of the polysilicon pattern 4 that is not covered by the resistive pattern 12, hence the P-Type gate region 4a is formed in the polysilicon pattern 4.

Here, the edge of the N-Type gate region 4b is uncovered by the resistive pattern 12, and into this uncovered part, both the N-Type and P-Type dopants are implanted, hence the overlapping region 4c is formed. Since the overlapping region 4c is formed, even if the misalignment occurs for resistive pattern 11 and 12, it is less likely that the region wherein the ion of dopant is not implanted is formed in the polysilicon pattern 4.

Thereafter, with the same method as of the first embodiment, the cobalt silicide film 9 is formed over the polysilicon pattern 4.

In the present embodiment, it is also possible to form the semiconductor device having the identical structure as that of the first embodiment. In such a case, similarly to the first embodiment, the formation of the cobalt suicide film 9 that is sufficiently formed into suicide in the entire part of the polysilicon pattern 4 becomes easier. Hence the high dispersion of the resistance of the cobalt silicide film 9 can be suppressed.

Moreover, since the overlapping region 4c is positioned closer to the P-Type channel region 20a, the P-Type dopant in the overlapping region 4c is less likely to diffuse over to the part that is positioned on the N-Type channel region 20b within the N-Type gate region 4b. Hence the gate depletion in the N-Type gate region 4b is less likely to occur. Furthermore, the ion density of the N-Type dopant in the overlapping region 4c is higher than that of the first embodiment, and the ion diffuses thermally due to annealing conducted in the status shown in FIG. 7, more specifically, in the status of the polysilicon film 13, while the overlapping region 4c is formed at least 0.5 μm away from the P-Type channel region 20a. Consequently, the N-Type dopant of the overlapping region 4c is less likely to diffuse to the part located on the P-Type channel region 20a in the P-Type gate region 4a. Thus the gate depletion is less likely to occur also in the P-Type gate region 4a.

In the process shown in FIG. 7, not regarding whether the N-Type region 13b is formed in the polysilicon film 13 or not, a P-Type region positioned on the P-channel transistor forming region 2a may be formed. In such a case, the resistive pattern 14 covers the part of the side of the N-channel transistor forming region 2b, and the pattern's edge part is positioned slightly towards the side of the N-channel transistor forming region 2b at a distance of, for example, at least 0.05 μm, from the perimeter between the P-channel transistor forming region 2a and the N-channel transistor forming region 2b. Here, a distance L4 between the edge of the resistive pattern 14 and the N-Type channel region 20b is at least 0.5 μm. This way, it is possible to obtain the same effect as of the first embodiment.

The present invention shall not be limited to the above-mentioned embodiments, and can be embodied with other kinds of modifications without departing from the main scope of the present invention.

For example, in the first embodiment, an N-Type gate region may be formed on the P-Type element region, and a P-Type gate region may be formed on the N-Type element region. In such case, in the process shown in FIG. 3, the P-channel transistor forming region 2a as well as the part of the side of the N-channel transistor forming region 2b in the polysilicon pattern 4 are covered with the resistive pattern 11, and ion implantation is conducted on them. Moreover, in the process shown in FIG. 4, the N-channel transistor forming region 2b as well as the part of the side of the P-channel transistor forming region 2a in the polysilicon pattern 4 are covered with the resistive pattern 12, and ion implantation is conducted on them. This way, it is possible to obtain the same effect as of the first embodiment.

1. A method of manufacturing a semiconductor device having an first conduction type transistor and a second conduction type transistor adjacently located and of which gate is connected each other, comprising:
a process for forming an element isolation film that isolates a first conduction type transistor forming region and a second conduction type transistor forming region on the semiconductor substrate;
a process for forming a gate dielectric film on each of the first conduction type transistor forming region and the second conduction type transistor forming region;
a process for forming a gate electrode on the two gate dielectric film and the element isolation film;
a process for forming a first conduction type gate region as well as implanting a first conduction type dopant into the gate electrode located on the first conduction type transistor forming region and on the part of the element isolation film;
a process for forming a second conduction type gate region as well as implanting a second conduction type dopant into the gate electrode located on the second conduction type transistor forming region and on the other part of the element isolation film; and
a process for forming a silicide film over the surface of the gate electrode;
wherein in the process for forming the second conduction type gate region, the second conduction type dopant is implanted in a way that overlaps with the part of the first conduction type gate electrode on the element isolation film.

2. The method of manufacturing a semiconductor device according to claim 1, wherein the process for forming the first conduction type gate region as well as the process for forming the second conduction type gate region respectively includes:
an implanting process of dopant, by forming a resist film on the region where the dopant is not implanted in the gate electrode, and implanting an ion using the resist film as a mask.

3. The method of manufacturing a semiconductor device according to claim 2, wherein:
in the process for forming the first conduction type gate region, a dopant is ion-implanted into the semiconductor substrate that is located in the first conduction type transistor forming region, while using the resist film, the element isolation film and the gate electrode as masks so as to form dopant layers for source and drain regions of the first conduction type transistor; and
in the process for forming the second conduction type gate region, the resist film is also formed on the first conduction type transistor forming region, a dopant is ion-implanted into the semiconductor substrate that is located in the second conduction type transistor forming region, while using the resist film, the element isolation film and the gate electrode as masks so as to form a dopant layer for source and drain regions of the second conduction type transistor.

4. A semiconductor device manufacturing method with each gate electrode of an adjacent first conduction type transistor and a second conduction type transistor being connected, the semiconductor device manufacturing method comprising:
a process for forming an element isolation film, for isolating a first conduction type transistor forming region and a second conduction type transistor forming region on the semiconductor substrate;
a process for forming gate dielectric film on each of the first conduction type transistor forming region and the second conduction forming region;
a process for forming a semiconductor film on the gate dielectric film and on the element isolation film;
a process for implanting a first conduction type dopant into the semiconductor film located on the part of the element isolation film and on the first conduction type transistor forming region;
a process for forming a gate electrode that is composed with the semiconductor film, on the element isolation film and on the gate dielectric film, by patterning the semiconductor film;
a process for implanting a second conduction type dopant into the gate electrode located on the part of the element isolation film and on the second conduction type transistor forming region;
a process for forming a silicide film over the surface of the gate electrode;
wherein in the process for implanting the second conduction type dopant into the gate electrode, the second conduction type dopant is implanted in a way that the gate electrode into which the first conduction type dopant is implanted overlaps on the element isolation film.

5. The method of manufacturing a semiconductor device, according to claim 4, further comprising:
a process for forming dopant layers which become source and drain regions for the first conduction type transistor, by implanting the first conduction type dopant into the semiconductor substrate that is located in the first conduction type transistor forming region, after the process for forming the gate electrode by patterning the semiconductor film;
wherein in the process for implanting the second conduction type dopant into the gate electrode, the dopant layers which become source and drain regions for the second conduction type transistor are further formed, by implanting the second conduction type dopant into the semiconductor substrate that is located in the second conduction type transistor forming region.

6. The method of manufacturing a semiconductor device method according to claim 4, wherein in the process for implanting a first conduction type dopant into the semiconductor film, the first conduction type dopant is implanted at a distance of at least 0.5 μm from a channel region of the second conduction type transistor.

7. A semiconductor device having an a first conduction type transistor and a second conduction type transistor adjacently located and of which gate electrode is connected each other, the semiconductor device comprising:
an element isolation film formed on a semiconductor substrate, and isolating a first conduction type transistor forming region and a second conduction type transistor forming region;
a gate dielectric film, located on the semiconductor substrate, and formed in the first conduction type transistor forming region and the second conduction type transistor forming region;
a first conduction type gate region, formed on the part of the element isolation film and on the gate electrode located on the first conduction type channel transistor forming region, and infused with a first conduction type dopant;
a second conduction type gate region, formed on the part of the element isolation film and on the gate electrode located on the second conduction type channel transistor forming region, and infused with a second conduction type dopant; and
a silicide film formed on the surface of the gate electrode;
wherein the second conduction type gate region is formed to overlap with the part of the first conduction type gate region over the element isolation film.

8. The semiconductor device according to claim 7, wherein the silicide film is a cobalt silicide film.

9. The semiconductor device, according to claim 7, wherein the length of the overlapping part of the first conduction type gate region and the second conduction type gate region is at least 0.1 μm.

10. The semiconductor device, according to claim 7, wherein the part, in which the first conduction type gate region and the second conduction type gate region overlap, is set apart at least 0.15 μm from both the source and drain regions that either of the transistors have.

11. The semiconductor device, according to claim 7, wherein the overlapping part of the first conduction type gate region and the second conduction type gate region is set apart at least 0.24 μm from the either of the channel regions that the transistors have.

12. The semiconductor device, according to claim 7, wherein the width of the gate electrode is 0.25 μm or less.
